(19) United States
(12) Patent Application Publication
(10) Pub. No.: US 2010/0015791 A1
(43) Pub. Date: Jan. 21, 2010

(54) SUPPLY APPARATUS, SEMICONDUCTOR MANUFACTURING APPARATUS AND SEMICONDUCTOR MANUFACTURING METHOD

(75) Inventors: Takashi Tanaka, Yamanashi (JP); Yusuke Saito, Yamanashi (JP); Mitsuaki Iwashita, Yamanashi (JP)

Correspondence Address: PEARNE & GORDON LLP, 1801 EAST 9TH STREET, SUITE 1200, CLEVELAND, OH, 44114-3108, US

(73) Assignee: TOKYO ELECTRON LIMITED, Tokyo (JP)

(21) Appl. No.: 12/405,620

(22) Filed: Mar. 17, 2009

(30) Foreign Application Priority Data
Jul. 18, 2008 (JP) 2008-187636

(51) Int. Cl. H01L 21/3205; B05C 5/00; B05B 7/16

(52) U.S. Cl. 438/597; 118/699; 118/302; 257/E21.295

(57) ABSTRACT

A film of uniform thickness can be formed on the entire surface of a substrate. A processing solution supply apparatus includes: a nozzle provided with a supply hole for discharging a plating solution toward a processing surface of a substrate held in a substantially horizontal direction; a temperature controller for accommodating therein the plating solution in an amount necessary for processing a preset number of substrates, for controlling a temperature of the accommodated plating solution up to a preset temperature; a heat insulator disposed between the nozzle and the temperature controller, for maintaining the plating solution, whose temperature has been controlled by the temperature controller, at the preset temperature; and a transporting mechanism for transporting the plating solution, whose temperature has been controlled up to the preset temperature by the temperature controller, toward the supply hole of the nozzle via the heat insulator.

### FIELD OF THE INVENTION

The present disclosure relates to a supply apparatus, a semiconductor manufacturing apparatus and a semiconductor manufacturing method for performing a liquid process such as plating on a target substrate to be processed.

### BACKGROUND OF THE INVENTION

In the design and manufacture of a semiconductor device, there has been an increasing demand for a higher operating speed and a higher level of integration. Meanwhile, it has been pointed out that electro-migration (EM) easily occurs due to a current density increase caused by a high-speed operation and wiring miniaturization, whereby wiring disconnection may be caused. This results in deterioration of reliability. For this reason, Cu (copper), Ag (silver) or the like having a low resistivity has been used as a wiring material formed on a substrate of the semiconductor device. Especially, since the copper has a resistivity of about 1.8 μΩ·cm and is expected to exhibit high EM tolerance, it is regarded as a material suitable for achieving the high speed of the semiconductor device.

In general, a damascene method has been utilized to form a copper wiring on the substrate, and this method involves forming a via and a trench on an insulating film by etching, and then filling them with a Cu wiring. Further, there has been made an attempt to enhance the EM tolerance of the semiconductor device by coating a metal film called a cap metal on the Cu wiring by electroless plating by means of supplying a plating solution containing CoWB (cobalt•tungsten•boron), CoWP (cobalt•tungsten•phosphorus), or the like on the surface of the substrate having the Cu wiring (see, for example, Patent Document 1).

The cap metal is formed by supplying the electroless plating solution on the surface of the substrate having the Cu wiring. For example, the substrate may be fixed on a rotary support, and by supplying the electroless plating solution while rotating the rotary support, a uniform liquid flow is generated on the substrate surface, whereby a uniform cap metal can be formed over the entire substrate surface (see, for example, Patent Document 2).

As for the electroless plating, however, it is known that a precipitation ratio of metal is largely affected by reaction conditions such as the composition and the temperature of the plating solution, and the like. Moreover, there has occurred a problem that by-products (residues) due to the plating reaction are generated in the form of slurry and remain on the substrate surface, impeding the uniform flow of the plating solution and making it impossible to replace the deteriorated electroless plating solution with new one. As a result, the reaction conditions on the substrate become locally different, making it difficult to form a cap metal having a uniform film thickness over the entire surface of the substrate. In addition, the substrate surface on which the cap metal is to be formed becomes to have a locally hydrophilic region or a locally hydrophobic region due to a difference in the surface material or sparseness or denseness of wiring. As a result, the electroless plating solution cannot be supplied onto the entire region of the substrate in a uniform manner, resulting in a failure of forming the cap metal having a uniform film thickness over the entire surface of the substrate.
Patent Document 1: Japanese Patent Laid-open Publication No. 2006-111938
Patent Document 2: Japanese Patent Laid-open Publication No. 2001-073157

### BRIEF SUMMARY OF THE INVENTION

As stated above, the conventional plating method has a drawback in that the electroless plating solution cannot be uniformly supplied onto the entire surface of the substrate, thus making it difficult to obtain the uniform film thickness over the entire surface of the substrate. Meanwhile, the formation of the uniform film thickness may be achieved at the expense of deterioration of throughput, and it has been difficult to perform the process consecutively.

In view of the foregoing, the present disclosure provides a supply apparatus, a semiconductor manufacturing apparatus and a semiconductor manufacturing method capable of reducing the amount of use of an electroless plating solution and also capable of forming a cap metal having a uniform film thickness over the entire surface of a substrate by suppressing an influence of by-products generated by a plating reaction.

In accordance with one aspect of the present disclosure, there is provided a supply apparatus including: a nozzle provided with a supply hole for discharging a plating solution toward a processing surface of a substrate held in a substantially horizontal direction; a temperature controller for accommodating therein the plating solution in an amount necessary for processing a preset number of substrates, for controlling a temperature of the accommodated plating solution up to a preset temperature; a heat insulator disposed between the nozzle and the temperature controller, for maintaining the plating solution, whose temperature has been controlled by the temperature controller, at the preset temperature; and a transporting mechanism for transporting the plating solution, whose temperature has been controlled up to the preset temperature by the temperature controller, toward the supply hole of the nozzle via the heat insulator.

In accordance with another aspect of the present disclosure, there is provided a semiconductor manufacturing apparatus for performing a plating process on a plurality of substrates consecutively, the apparatus including: a temperature controller for accommodating therein a preset amount of plating solution necessary for processing a single sheet of substrate and for controlling the accommodated plating solution up to a preset temperature; a holding unit for holding the substrates one by one at a preset position; a nozzle provided with a supply hole for discharging the plating solution, whose temperature has been controlled by the accommodation in the temperature controller, toward a processing surface of the substrate held by the holding unit; a transporting mechanism for transporting the whole amount of plating solution, whose temperature has been controlled up to the preset temperature by the accommodation in the temperature controller, toward the supply hole of the nozzle whenever processing a single sheet of substrate held by the holding unit; and a control unit for controlling timing for transporting the plating solution by the transporting mechanism. Further, in accordance with still another aspect of the present disclosure, there is provided a semiconductor manufacturing method including: accommodating a preset amount of plating solution necessary for processing a single sheet of substrate in a temperature control vessel; heating the plating solution accommodated in the temperature control vessel; and after the plating solution reaches a preset temperature, transporting the whole amount of plating solution accommodated in the temperature control vessel at one time toward a supply hole, provided in a nozzle connected to the temperature control vessel, to discharge the plating solution onto a processing surface of the substrate at one time.

In accordance with the present disclosure, it is possible to provide a supply apparatus and a semiconductor manufacturing apparatus and method capable of achieving a formation of a uniform film thickness on a substrate surface.

### BRIEF DESCRIPTION OF THE DRAWINGS

The disclosure may best be understood by reference to the following description taken in conjunction with the following figures:

FIG. 1 provides a plane view illustrating a configuration of a semiconductor manufacturing apparatus in accordance with an embodiment of the present disclosure;

FIG. 2 sets forth a cross sectional view of an electroless plating unit of the semiconductor manufacturing apparatus in accordance with the embodiment of the present disclosure;

FIG. 3 presents a plane view of the electroless plating unit of the semiconductor manufacturing apparatus in accordance with the embodiment of the present disclosure;

FIG. 4 depicts a schematic view illustrating an arm unit of the electroless plating unit of the semiconductor manufacturing apparatus in accordance with the embodiment of the present disclosure;

FIG. 5 offers a schematic view illustrating a configuration of a first arm in accordance with the embodiment of the present disclosure;

FIG. 6 provides a flowchart to describe an operation of the electroless plating unit in accordance with the embodiment of the present disclosure;

FIG. 7 sets forth a diagram for describing an entire process of the electroless plating unit in accordance with the embodiment of the present disclosure;

FIG. 8 presents a diagram for describing a plating process of the electroless plating unit in accordance with the embodiment of the present disclosure;

FIG. 9 is a chart for illustrating a relationship of a plating solution temperature and a plated film forming rate with respect to a heating time for a plating processing solution having a certain composition;

FIG. 10 is a chart for illustrating a relationship of a plating solution temperature and a plated film forming rate with respect to a heating time for each of a plurality of plating processing solutions having different TMAH compositions used as a PH adjuster;

FIG. 11 illustrates a state in which the plating process described in FIG. 6 is performed on a plurality of substrates W; and

FIG. 12 also shows a state in which the plating process described in FIG. 6 is performed on a plurality of substrates W.

### DETAILED DESCRIPTION OF THE INVENTION

A general electroless plating process includes a pre-cleaning process, a plating process, a post-cleaning process, a rear surface/end surface cleaning process, and a drying process. Here, the pre-cleaning process is a process for hydrophilicizing a wafer to be processed. The plating process is a process for performing plating by supplying a plating solution onto the wafer. The post-cleaning process is a process for removing residues generated by a plating precipitation reaction. The rear surface/end surface cleaning process is a process for removing residues which are generated during the plating process on the rear surface and the end surface of the wafer. The drying process is a process for drying the wafer. Each of these processing steps is implemented by combining a rotation of the wafer, a supply of a cleaning solution or a plating solution onto the wafer, and so forth.

In the plating process in which a processing solution such as the plating solution is supplied onto the substrate, there may be generated a non-uniformity in the film thickness of a film (plated film) generated by the plating process due to a variation of a processing solution supply, or the like. Especially, in case that the substrate has a large size, the non-uniformity of the film thickness becomes conspicuous. A semiconductor manufacturing apparatus in accordance with an embodiment of the present disclosure is designed to solve the problem of film thickness variation•non-uniformity especially in the plating process among each process of the electroless plating process, as well as to improve throughput.

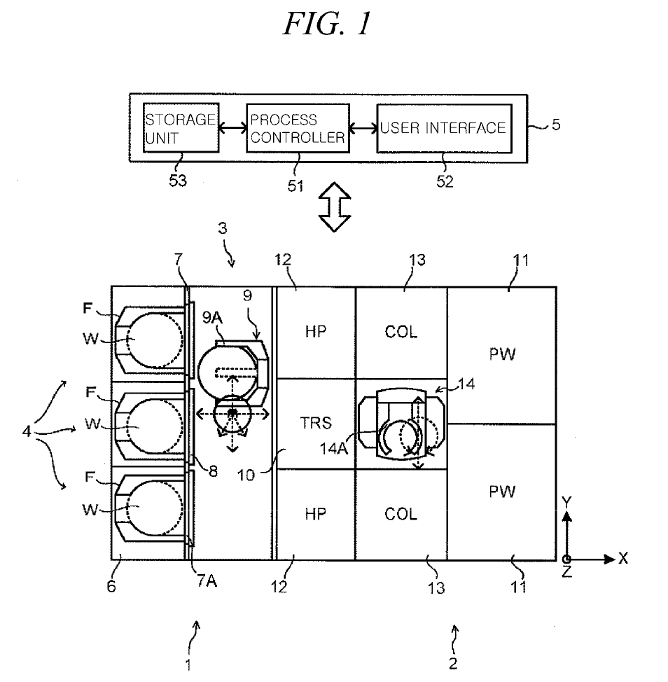

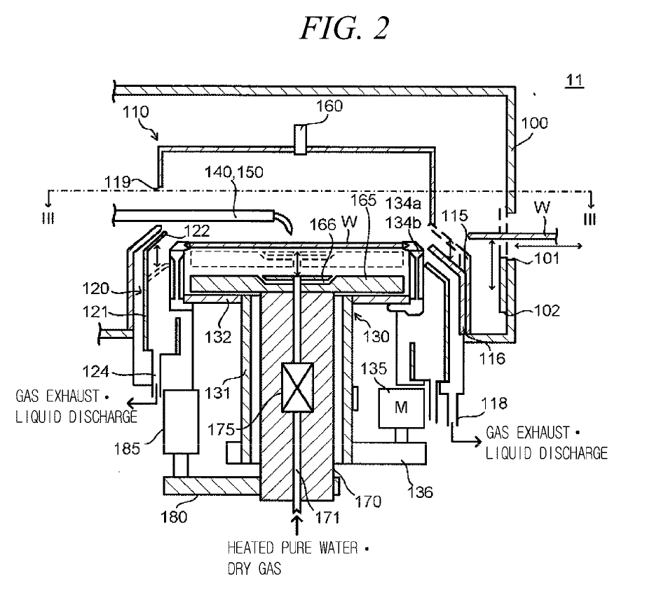

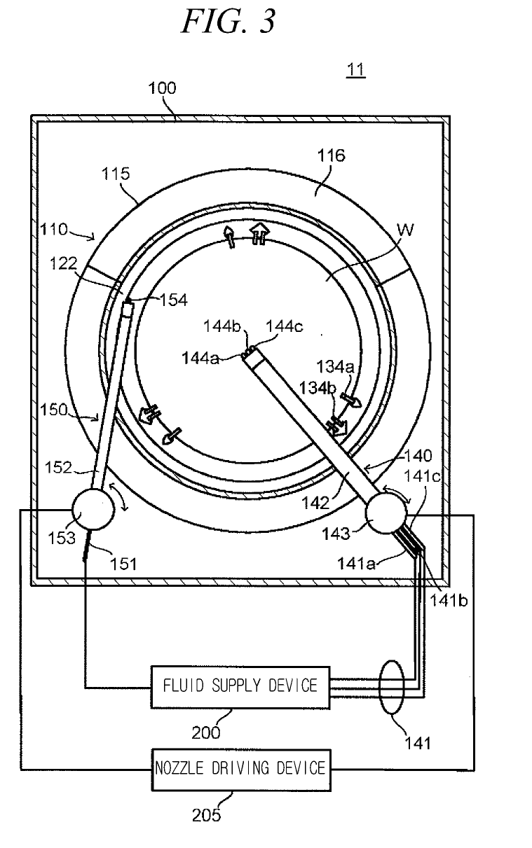

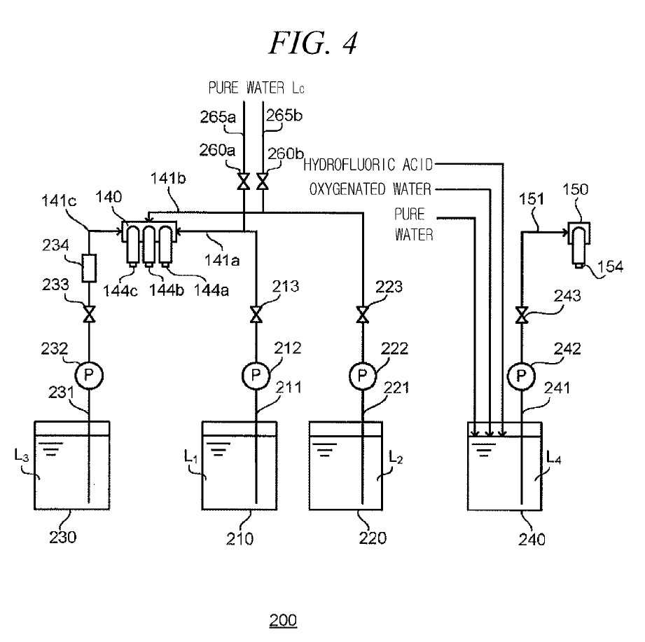

Hereinafter, the embodiment of the present disclosure will be described in detail with reference to the accompanying drawings. FIG. 1 is a plane view showing a configuration of the semiconductor manufacturing apparatus in accordance with the embodiment of the present disclosure, and FIGS. 2 and 3 set forth a cross sectional view and a plane view of an electroless plating unit of the semiconductor manufacturing apparatus in accordance with the embodiment of the present disclosure, respectively. FIG. 4 depicts a schematic view illustrating an arm unit for supplying a plating solution in the electroless plating unit.

As shown in FIG. 1, the semiconductor manufacturing apparatus in accordance with the embodiment of the present disclosure includes a loading/unloading unit 1, a processing unit 2, a conveyance unit 3 and a control unit 5.

The loading/unloading unit 1 is a device for loading and unloading plural substrates W into and out of the semiconductor manufacturing apparatus via FOUPs (Front Opening Unified Pods) F. As shown in FIG. 1, the loading/unloading unit 1 includes three loading/unloading ports 4 arranged in Y direction along the front face (lateral side of X direction of FIG. 1) of the apparatus. Each loading/unloading port 4 has a mounting table 6 for mounting the FOUP F thereon. A partition wall 7 is formed on the rear surface of each gate loading/unloading port 4, and a window 7A corresponding to the FOUP F is formed at the partition wall 7 to be positioned above the mounting table 6. Each window 7A is provided with an opener 8 for opening or closing a lid of the FOUP F. The lid of the FOUP F is opened or closed by the opener 8.

The processing unit 2 is a group of processing units for performing each of the above-described processes on the substrates W sheet by sheet. The processing unit 2 includes a transfer unit TRS 10 for performing a transfer of the substrate W with respect to the conveyance unit 3; electroless plating units PW 11 for performing an electroless plating process and pre- and post-processes therefore on the substrate W; heating units HP 12 for heating the substrate W before and after the plating process; cooling units COL 13 for cooling the substrate W heated by the heating units 12; and a second substrate transfer mechanism 14 disposed in a substantially center portion of the processing unit 2 while being surrounded by the group of these units and serving to transfer the substrate W between the respective units.

The transfer unit 10 includes substrate transfer devices (not shown) vertically arranged in two levels, for example. The upper and lower substrate transfer devices can be used complementarily depending on the purposes of use. For example, the lower substrate transfer device may be used to temporarily mount thereon the substrate W loaded from the loading/unloading port 4, while the upper substrate transfer device may be used to temporarily mount thereon the substrate W to be unloaded back into the loading/unloading port 4.

The two heating units 12 are disposed at locations adjacent to the transfer unit 10 along the Y direction. Each heating unit 12 includes, for example, heating plates vertically arranged in four levels. The two cooling units 13 are disposed at locations adjacent to the second substrate transfer mechanism 14 in the Y direction. Each cooling unit 13 includes, for example, cooling plates vertically arranged in four levels. The two electroless plating units 11 are arranged in the Y direction along the cooling units 13 and the second substrate transfer mechanism 14 located adjacent to them.

The second substrate transfer mechanism 14 includes, for example, two transfer arms 14A vertically arranged in two levels. Each of the upper and lower transfer arms 14A is configured to be movable up and down and rotatable along a horizontal direction. With this configuration, the second substrate transfer mechanism 14 transfers the substrates W between the transfer unit 10, the electroless plating units 11, the heating units 12 and the cooling unit 13 by the transfer arms 14A.

The conveyance unit 3 is a transfer mechanism located between the loading/unloading unit 1 and the processing unit 2 and serving to transfer the substrates W sheet by sheet. A first substrate transfer mechanism 9 for transferring the substrates W sheet by sheet is disposed in the conveyance unit 3. The substrate transfer mechanism 9 includes, for example, two transfer arms 9A vertically arranged in two levels and movable along a Y direction, and it performs a transfer of the substrates W between the loading/unloading unit 1 and the processing unit 2. Likewise, each transfer arm 9A is configured to be movable up and down and rotatable along a horizontal direction. With this configuration, the first substrate transfer mechanism 9 transfers the substrates W between the FOUPs F and the processing unit 2 by the transfer arms 9A.

The control unit 5 includes a process controller 51 having a microprocessor; a user interface 52 connected with the process controller 51; and a storage unit 53 for storing therein computer programs for regulating the operation of the semiconductor manufacturing apparatus in accordance with the present embodiment, and controls the processing unit 2, the conveyance unit 3, and so forth. The control unit 5 is on-line connected with a non-illustrated host computer and controls the semiconductor manufacturing apparatus based on instructions from the host computer. The user interface 52 is an interface including, for example, a key board, a display, and the like, and the storage unit 53 includes, for example, a CD-ROM, a hard disk, a nonvolatile memory or the like.

Now, the operation of the semiconductor manufacturing apparatus in accordance with the present embodiment will be explained. A substrate W to be processed is previously accommodated in a FOUP F. First, the first substrate transfer mechanism 9 takes the substrate W out of the FOUP F through the window 7A and transfers it to the transfer unit 10. Once the substrate W is transferred to the transfer unit 10, the second substrate transfer mechanism 14 transfers the substrate W from the transfer unit 10 to the hot plate of the heating unit 12 by using the transfer arm 14A.

The heating unit 12 heats (pre-bakes) the substrate W up to a preset temperature, to thereby eliminate organic materials attached on the surface of the substrate W. After the heating process, the second substrate transfer mechanism 14 delivers the substrate W from the heating unit 12 into the cooling unit 13. The cooling unit 13 cools the substrate W.

After the completion of the cooling process, the second substrate transfer mechanism 14 transfers the substrate W into the electroless plating unit 11 by using the transfer arm 14A. The electroless plating unit 11 performs an electroless plating process on a wiring formed on the surface of the substrate W or the like.

After the completion of the electroless plating process, the second substrate transfer mechanism 14 transfers the substrate W from the electroless plating unit 11 to the hot plate of the heating unit 12. The heating unit 12 performs a post-baking process on the substrate W to remove organic materials contained in a plated film (cap metal) formed by the electroless plating as well as to enhance adhesiveness between the plated film and the wiring or the like. After the completion of the post-baking process, the second substrate transfer mechanism 14 transfers the substrate W from the heating unit 12 into the cooling unit 13. The cooling unit 13 cools the substrate W again.

After the completion of the cooling process, the second substrate transfer mechanism 14 transfers the substrate W to the transfer unit 10. Then, the first substrate transfer mechanism 9 returns the substrate W mounted on the transfer unit 10 back into a preset position in the FOUP F by using the transfer arm 9A.

Afterwards, these series of processes are consecutively performed on a plurality of substrates. Further, it may be possible to previously process a dummy wafer at an initial stage and then to facilitate the stabilization of a processing state of each unit. As a result, reproducibility of the process can be improved.

Subsequently, the electroless plating unit 11 of the semiconductor manufacturing apparatus in accordance with the present embodiment will be explained in detail in conjunction with FIGS. 2 to 4. As shown in FIG. 2, the electroless plating unit 11 (hereinafter, simply referred to as a “plating unit 11”) includes an outer chamber 110, an inner chamber 120, a spin chuck 130, a first and a second fluid supply unit 140 and 150, a gas supply unit 160, a back plate 165.

The outer chamber 110 is a processing vessel installed inside a housing 100, for performing the plating process therein. The outer chamber 110 is formed in a cylinder shape to surround an accommodation position of the substrate W and is fixed on the bottom surface of the housing 100. Installed at a lateral side of the outer chamber 110 is a window 115 through which the substrate W is loaded and unloaded, and the window 115 is opened or closed by a shutter mechanism 116. Further, an openable/closable shutter mechanism 119 for operating the first and second fluid supply units 140 and 150 is installed at a lateral side of the outer chamber 110 facing the window 115. Moreover, a gas supply unit 160 is installed on the top surface of the outer chamber 110, and a drain unit 118 for discharging a gas, the processing solution or the like is provided at a lower portion of the outer chamber 110.

The inner chamber 120 is a vessel for receiving therein the processing solution dispersed from the substrate W, and it is installed inside the outer chamber 110. The inner chamber 120 is formed in a cylinder shape between the outer chamber 110 and the accommodation position of the substrate W, and it includes a drain unit 124 for the discharge of a gas or a liquid. The inner chamber 120 is configured to be movable up and down inside the outer chamber 110 by a non-illustrating elevating mechanism such as a gas cylinder or the like. Specifically, the end of its upper end portion 122 is moved up and down between a position (processing position) slightly higher than the accommodation position of the substrate W and a position (retreat position) lower than the processing position. Here, the processing position is a position where the electroless plating process is performed on the substrate W, and the retreat position is a position where the loading/unloading of the substrate W, cleaning of the substrate W or the like is performed.

The spin chuck 130 is a substrate fixing mechanism for holding the substrate W thereon in a substantially horizontal manner. The spin chuck 130 includes a rotary cylinder body 131; an annular rotary plate 132 horizontally extended from the upper end of the rotary cylinder body 131; supporting pins 134a installed at an outer peripheral end of the rotary plate 132 at a same distance, for supporting the outer periphery portion of the substrate W; and pressing pins 134b for pressing the outer peripheral surface of the substrate W. As illustrated in FIG. 3, the supporting pins 134a and the pressing pins 134b are arranged, for example, in sets of three along the circumferential direction. The supporting pins 134a are fixtures which support and fix the substrate W at the preset position, and the pressing pins 134b are pressing devices which press the substrate W downward. A motor 135 is installed at a lateral side of the rotary cylinder body 131, and an endless belt 136 is wound between a driving shaft of the motor 135 and the rotary cylinder body 131. That is, the rotary cylinder body 131 is rotated by the motor 135. The supporting pins 134a and the pressing pins 134b are rotated in the horizontal direction (planar direction of the substrate W), whereby the substrate W supported by them is also rotated.

The gas supply unit 160 dries the substrate W by supplying a nitrogen gas or clean air into the outer chamber 110. The supplied nitrogen gas or clean air is re-collected via the drain unit 118 or 124 installed at the lower end of the outer chamber 110.

The back plate 165 is installed between the holding position of the substrate W by the spin chuck 130 and the rotary plate 132, facing the bottom surface of the substrate W held on the spin chuck 130. The back plate 165 has a heater embedded therein and is connected with a shaft 170 which penetrates the center of axis of the rotary cylinder body 131. Provided in the back plate 165 is a flow path 166 which is opened at plural positions on the surface thereof, and a fluid supply path 171 is formed to penetrate through the flow path 166 and the center of axis of the shaft 170. A heat exchanger 175 is disposed in the fluid supply path 171. The heat exchanger 175 regulates a processing fluid such as pure water or a dry gas at a preset temperature. That is, the back plate 165 functions to supply the humidity-controlled processing fluid toward the bottom surface of the substrate W. An elevating mechanism 185 such as an air cylinder or the like is connected to a lower end portion of the shaft 170 via a coupling member 180. The back plate 165 is moved up and down between the substrate W held on the spin chuck 130 and the rotary plate 132 by the elevating mechanism 185 and the shaft 170.

As shown in FIG. 3, the first and second fluid supply units 140 and 150 supply the processing solution onto the top surface of the substrate W held by the spin chuck 130. The first and second fluid supply units 140 and 150 have a fluid supply device 200 for storing therein a fluid such as the processing solution; and a nozzle driving device 205 for driving a supply nozzle. Each of the first and second fluid supply units 140 and 150 is installed inside the housing 100 so as to allow the outer chamber 110 to be interposed therebetween.

The first fluid supply unit 140 includes a first pipe 141 connected with the fluid supply device 200; a first arm 142 supporting the first pipe 141; a first rotation driving mechanism 143 for rotating the first arm 142 with respect to a basal end of the first arm 142 by using a stepping motor or the like disposed at that basal end of the first arm 142. The first fluid supply unit 140 has a function of supplying the processing fluid such as the electroless plating processing solution or the like. The first pipe 141 has pipes 141a to 141c for supplying three kinds of fluids individually, and these pipes 141a to 141c are respectively connected with nozzles 144a to 144c at the leading end portion of the first arm 142. In the pre-cleaning process, a processing solution and pure water are supplied from the nozzle 144a; in the post-cleaning process, a processing solution and pure water are supplied from the nozzle 144b; and in the plating process, a plating solution is supplied from the nozzle 144c.

Likewise, the second fluid supply unit 150 includes a second pipe 151 connected with the fluid supply device 200; a second arm 152 supporting the second pipe 151; and a second rotation driving mechanism 153 disposed at the basal end of the second arm 152, for rotating the second arm 152. The second pipe 151 is connected with a nozzle 154 at the leading end portion of the second arm 152. The second fluid supply unit 150 has a function of supplying a processing fluid for processing the outer periphery portion (periphery portion) of the substrate W. The first and second arms 142 and 152 are rotated above the substrate W held on the spin chuck 130 via the shutter mechanism 119 installed in the outer chamber 110.

Here, the fluid supply device 200 will be described in detail with reference to FIG. 4. The fluid supply device 200 supplies the processing fluid to the first and second fluid supply units 140 and 150. As illustrated in FIG. 4, the fluid supply device 200 includes a first tank 210, a second tank 220, a third tank 230 and a fourth tank 240.

The first tank 210 stores therein a pre-cleaning processing solution L₁ used for the pre-treatment of the electroless plating process of the substrate W. The second tank 220 stores therein a post-cleaning processing solution L₂ used for the post-treatment of the electroless plating process of the substrate W. The first and second tanks 210 and 220 include temperature control mechanisms (not shown) for controlling the temperatures of the processing solutions L₁ and L₂ at preset temperature levels, and are connected with a pipe 211 coupled with the first pipe 141a and a pipe 221 coupled with the first pipe 141b, respectively. The pipes 211 and 221 includes pumps 212 and 222 and valves 213 and 223, respectively. The processing solutions L₁ and L₂ whose temperatures are controlled at the preset temperature levels are supplied into the first pipes 141a and 141b, respectively. That is, by operating each of the pumps 212 and 222 and the valves 213 and 223, the processing solutions L₁ and L₂ are transported to the nozzles 144a and 144b via the first pipes 141a and 141b, respectively.

The third tank 230 stores therein a plating solution L₃ for use in processing the substrate W. The third tank 230 is connected with a pipe 231 coupled to the first pipe 141c. Installed on the pipe 231 are a pump 232, a valve 233 and a heater (e.g., a heat exchanger 234) for heating the plating solution L₃. That is, the temperature of the plating solution L₃ is controlled by the heater 234, and the plating solution L₃ is transported to the nozzle 144c via the first pipe 141c by the cooperation of the pump 232 and the valve 233. The pump 232 may function as a transporting mechanism, such as a pressurizing mechanism or a force-feed mechanism, for transporting the plating solution L₃.

The fourth tank 240 stores therein an outer periphery processing solution L₄ for use in processing the outer periphery portion of the substrate W. The fourth tank 240 is connected with a pipe 241 coupled to the second pipe 151. A pump 242 and a valve 243 are installed on the pipe 241. That is, the outer periphery processing solution L₄ is sent out into the nozzle 154 via the second pipe 151 by the cooperation of the pump 242 and the valve 243.

Further, a pipe for supplying, e.g., hydrofluoric acid, a pipe for supplying oxygenated water and a pipe for supplying pure water L₀ are also connected with the fourth tank 240. That is, the fourth tank 240 also functions to mix these solutions at a preset mixture ratio.

Further, pipes 265a and 265b for supplying pure water L₀ are connected with the first pipe 141a and 141b, respectively. A valve 260a is installed on the pipe 265a, and a valve 260b is installed on the pipe 265b. That is, the nozzles 144a and 144b are also capable of supplying the pure water L₀.

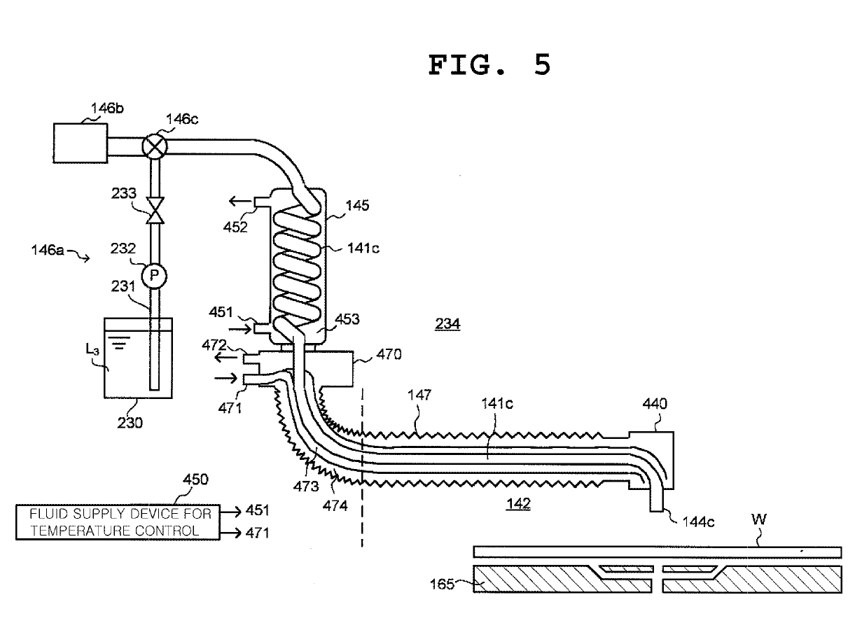

Here, the first arm 142 of the first fluid supply unit 140 will be explained in detail with reference to FIG. 5. FIG. 5 is a schematic configuration view of the first arm 142. As illustrated in FIG. 5, the first arm 142 includes a temperature controller 145; a pump mechanism having a supply mechanism 146a, a re-suction mechanism 146b and a coupling mechanism 146c; and a heat insulator 147. That is, in the plating unit 11 in accordance with the present embodiment, the heater 234 shown in FIG. 4 is constituted by the temperature controller 145 and the heat insulator 147 installed at the first arm 142.

The temperature controller 145 is a heater mechanism for heating the plating processing solution or the like up to a temperature adequate for a target process. The temperature controller 145 has an air-tightly sealed housing through which the pipe 141c is arranged, and is provided with a fluid inlet port 451 for introducing a temperature control fluid (for example, heated water) supplied from a fluid supply device 450 for temperature control and a fluid outlet port 452 for discharging the fluid. The fluid supplied from the fluid inlet port 451 is flown through an inner space 453 of the housing, and then the fluid comes into contact with the pipe 141c, thus heating the plating processing solution flowing through the pipe 141c. Then, the fluid is discharged from the fluid outlet port 452. The pipe 141c inside the temperature controller 145 is desirably formed in, for example, a spiral shape to increase the contact area with the temperature control fluid. The temperature up to which the plating processing solution is heated is determined depending on the composition of the plating processing solution, film forming conditions, and the like, and it may be, for example, about 20 to 90° C.

The supply mechanism 146a includes the above-mentioned pump 232 and valve 233, and it serves as a transporting mechanism for transporting the plating solution L₃ stored in the third tank 230 into the nozzle 144c through the pipe 141c. Further, in the example shown in FIGS. 4 and 5, though the plating processing solution is transported by the pump 232 and valve 233 serving as the transporting mechanism, the present disclosure is not limited to this configuration. For example, a force-feed mechanism or a pressurizing mechanism such as a diaphragm pump can be used as the pump 232 instead. The re-suction mechanism 146b functions to suck the plating solution collected at the leading end of the nozzle 144c after the completion of the supply of the plating solution onto the substrate processing surface. The coupling mechanism 146c couples a pipe from the supply mechanism 146a, a pipe to the re-suction mechanism 146b and a pipe to the temperature controller 145. The coupling mechanism 146c may be integrated as one body with the valve 233 or can be provided separately. The supply mechanism 146a transports a preset amount of processing solution toward the nozzle 144c at a certain flow rate or at a certain timing based on a processing solution supply instruction from the process controller 51.

The heat insulator 147 is disposed between the temperature controller 145 and the nozzle 144c and functions to maintain the temperature of the plating processing solution heated by the temperature controller 145 until the plating processing solution is discharged out from the nozzle 144c. The heat insulator 147 is provided independently of the temperature controller 145 and it has an air-tightly sealed housing through which the pipe 141c is installed, and is provided with a fluid inlet port 471 for introducing a temperature control fluid supplied from the fluid supply device 450 for temperature control and a fluid outlet port 472 for discharging the fluid. The fluid supplied from the fluid supply device 450 for temperature control may be the same as the one supplied to the temperature controller 145 or may be different from it. Inside the heat insulator 147, a heat-insulating pipe 473 connected with the fluid inlet port 471 is in contact with the pipe 141c, whereby the plating processing solution in the pipe 141c is allowed to be maintained at the preset temperature. The heat-insulating pipe 473 is extended up to the vicinity of the nozzle 144c along the pipe 141c of the heat insulator 147 so as to keep the temperature of the processing solution until the processing solution is discharged out from the nozzle 144c. The heat-insulating pipe 473 is opened inside a nozzle housing 440 accommodating the nozzle 144c therein and is allowed to communicate with an inner space 474 of the heat insulator 147. That is, the heat insulator 147 has a threefold structure (threefold pipe structure) including the pipe 141c provided in the center of the cross section thereof; the heat-insulating pipe 473 installed to be thermally in contact with the outer periphery of the pipe 141c; and the space 474 provided outside the heat-insulating pipe 473. A heat-insulating fluid supplied from the fluid inlet port 471 keeps the temperature of the plating processing solution while passing through the heat-insulating pipe 473 until it reaches the nozzle housing 440, and then is flown through the inner space 474 of the heat insulator 147 to be finally discharged from the fluid outlet port 472. The fluid flowing through the space 474 functions to insulate the fluid flowing through the heat-insulating pipe 473 (and the plating processing solution flowing through the pipe 141c inside) from the exterior atmosphere outside the heat insulator 147. Accordingly, heat loss of the fluid flowing through the heat-insulating pipe 473 can be suppressed, and a heat transfer from the fluid in the heat-insulating pipe 473 to the plating processing solution in the pipe 141c can be effectively performed. Since the heat insulator 147 is provided at the first arm 142 driven by the nozzle driving device 205, its housing is desirably formed in a shape capable of keeping up with movements, for example, in a serpentine shape or the like. The temperature control fluid (heated water) supplied into the fluid inlet port 471 may be the same as the one supplied into the fluid inlet port 451 or may be a different fluid having a temperature difference.

As for the pipe 141c's portion in which the plating processing solution is heated and kept warm by the temperature controller 145 and the heat insulator 147, its thickness or length is determined such that an entire amount of plating processing solution for processing a preset number of substrates W can be heated and kept warm at the same time. That is, the plating processing solution heated and kept at a certain temperature by the temperature controller 145 and the heat insulator 147 are all used up in the plating process for the preset number of substrates W, and a plating solution newly heated by the temperature controller 145 and kept warm by the heat insulator 147 is supplied again for next target substrates W. In this way, plating processes for the following target substrates are performed by the newly heated and insulated plating processing solution.

Moreover, it may be also possible to set the pipe 141c's portion in which the plating solution is heated and kept warm by the temperature controller 145 and the heat insulator 147 to have a volume corresponding to the amount of plating processing solution for processing a single sheet of substrate W. In such case, uniform plating process can be implemented when processing a plurality of substrates W consecutively. For example, if the amount of plating processing solution heated and insulated by the temperature controller 145 and the heat insulator 147 at one time is set to correspond to the processing of the plurality of substrates W, there occurs a difference between a plating solution heating time for the first plating process and a plating solution heating time for the last plating process. Typically, since the plating processing solution starts to be deteriorated as it is heated, uniform plating process may not be achieved if the plating processing solution for the processing of the plurality of substrates is heated at one time. However, by setting the amount of the plating processing solution heated by the temperature controller 145 and the heat insulator 147 at one time to correspond to the amount for the processing of the single substrate W and repeating it required times, more uniform plating process can be expected. An example volume of the plating processing solution kept warm by the heat insulator 147 may be the same as, e.g., about 1/10 of the volume of the plating solution heated by the temperature controller 145. For instance, the volume of the plating processing solution heated by the temperature controller 145 may be about 115 ml and the volume of the plating processing solution kept warm by the heat insulator 147 may be about 10 ml.

Now, the operation of the first arm 145 will be explained with reference to FIG. 5. If the process controller 51 instructs the fluid supply device 200 to supply the plating processing solution L₃, the fluid supply device 200 drives the pump 232 and opens the valve 233. Detailed control of the supply timing for the plating processing solution L₃ is conducted by way of controlling the valve 233. Meanwhile, if the process controller 51 instructs the fluid supply device 200 to stop the supply of the plating processing solution L₃, the fluid supply device 200 closes the valve 233 and stops the pump 232, and sucks the plating processing solution L₃ left in the pipe 141c by operating the re-suction mechanism 146b, whereby the plating processing solution L₃ can be prevented from dropping down onto the substrate W from the nozzle 144c. Further, the fluid supply device 450 for temperature control always supplies the temperature control fluid to the temperature controller 145 and the heat insulator 147 during the plating process because the heating time of the plating processing solution L₃ can be controlled by adjusting a processing time or the like as will be described later.

In the present embodiment, the heater 234 in the plating unit 11 heats and adjusts the plating processing solution L₃ up to a preset plating process temperature by using the temperature controller 145 and the heat insulator 147 installed at the first arm 142. The configuration is designed by considering the influence of the lifetime of the plating processing solution. When performing the plating process on the plurality of substrates W consecutively, it is possible to heat the whole plating processing solution L₃ to be used in their processing up to a preset temperature at one time. In such case, as for the plating solution used in a plating process at an early stage and the plating solution used in a plating process at a late stage, there occurs a time difference until they are actually used after reaching the preset temperature. However, the inventor of the present application has found out that it is impossible to preserve the plating processing solution for a long time after its temperature is controlled (i.e., the characteristic of the plating processing solution changes with the lapse of time after it reaches the preset temperature). In this regard, the reason for installing the heater 234, which heats the minimum required amount of plating solution, inside the first arm is to uniform the characteristic of the plating processing solution during the plating process. Especially, when processing the plurality of substrates, it becomes possible to uniform the characteristics of plating processing solutions used for each substrate. Besides, the apparatus can be made compact, and a temperature decrease of the plating processing solution can be suppressed.

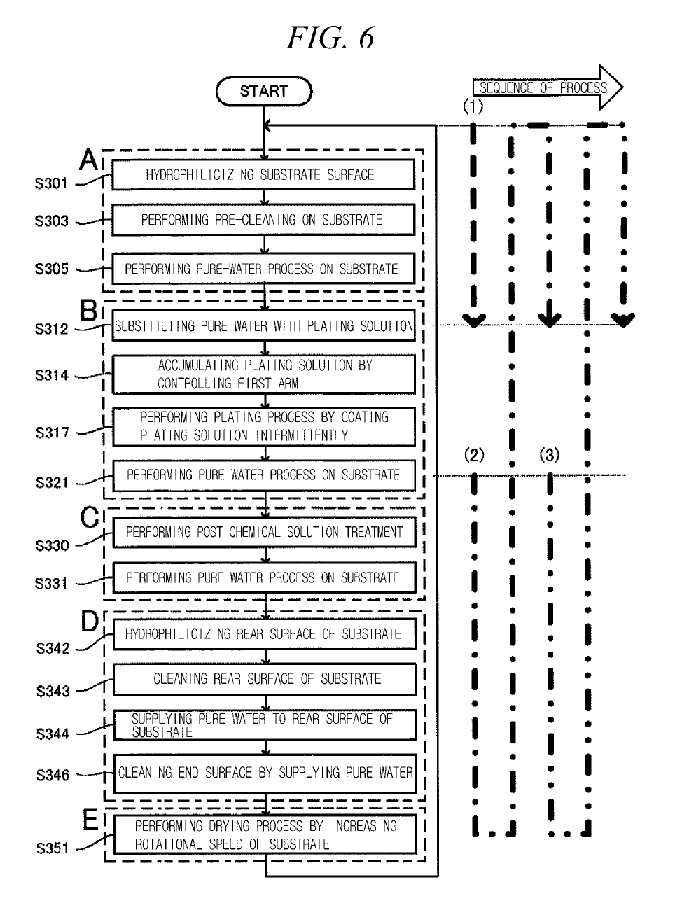

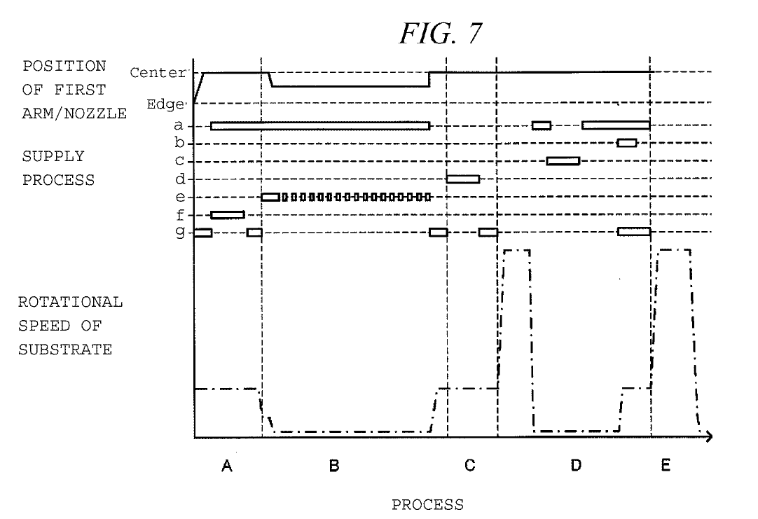

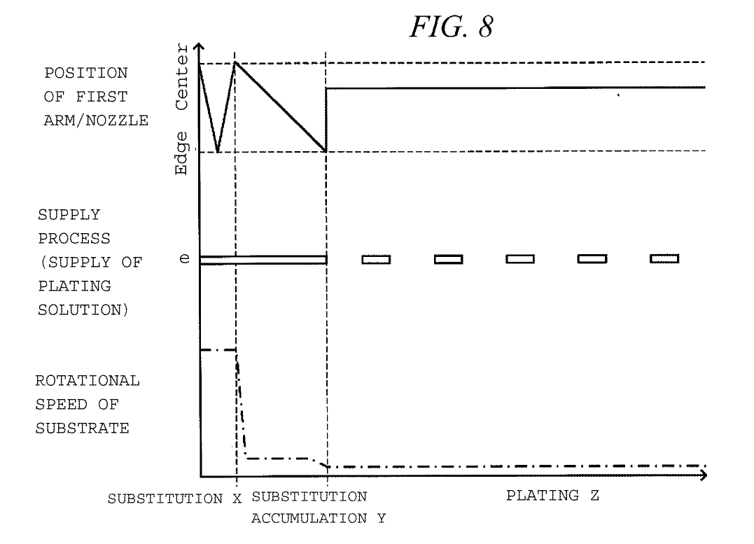

Now, the operation of the electroless plating unit 11 in accordance with the present embodiment will be described with reference to FIGS. 1 to 8. FIG. 6 provides a flowchart to describe the operation of the electroless plating unit 11 in accordance with the present embodiment, especially, a plating process operation thereof. FIG. 7 illustrates an entire process sequence of the electroless plating unit 11, and FIG. 8 illustrates a process sequence of the plating process of the electroless plating unit 11 in accordance with the present embodiment. As shown in FIG. 6, the plating unit 11 in accordance with the present embodiment performs five processing steps including a pre-cleaning process (“A” in the figure), a plating process (“B” in the figure), a post-cleaning process (“C” in the figure), a rear surface/end surface cleaning process (“D” in the figure) and a drying process (“E” in the figure). Further, as shown in FIG. 7, the plating unit 11 performs seven supply processes of processing liquids including: a rear surface pure water supply a for supplying heated pure water to the rear surface of the substrate; an end surface cleaning b for cleaning the end surface of the substrate; a rear surface cleaning c for cleaning the rear surface of the substrate; a post-cleaning d for cleaning the substrate after a plating process; the plating process e; a pre-cleaning f for cleaning the substrate prior to the plating process; and a pure water supply g for controlling the hydrophilicity of the substrate W. FIG. 8 shows the processing sequence of the plating process e shown in FIG. 7 in further detail.

The first substrate transfer mechanism 9 takes substrate W sheet by sheet from the FOUP F of the loading/unloading unit 1 and loads each substrate W into the transfer unit 10 of the processing unit 2. Once the substrate W is loaded, the second substrate transfer mechanism 14 transfers the substrate W into the heating unit 12 and the cooling unit 13 in which the substrate W is processed by a heat treatment therein. Upon the completion of the heat treatment, the second substrate transfer mechanism 14 transfers the substrate W into the electroless plating unit 11.

First, the process controller 51 carries out the pre-cleaning process A. The pre-cleaning process A includes a hydrophilicizing process, a pre-cleaning process, and a pure water process.

The process controller 51 rotates the substrate W held on the spin chuck 130 by driving the motor 135. If the spin chuck 130 is rotated, the process controller 51 instructs the nozzle driving device 205 to drive the first fluid supply unit 140. The nozzle driving device 205 moves the first arm 142 to a preset position on the substrate W (e.g., a position at which the nozzle 144a is located at the center of the substrate W) by operating the first rotation driving mechanism 143. Further, the nozzle driving device 205 also moves the second arm 152 to a periphery portion of the substrate W by operating the second rotary driving mechanism 153. When the two arms reach their preset positions, the process controller 51 instructs the fluid supply device 200 to perform the hydrophilicizing process (S301). Then, the fluid supply device 200 supplies a preset amount of pure water L₀ into the nozzle 144a by opening the valve 260a (supply process g in FIG. 7). At this time, the nozzle 144a is located above the substrate W by, e.g., about 0.1 to 20 mm. Likewise, the fluid supply unit 200 supplies the processing liquid L₄ into the nozzle 154 by opening the valve 243. In this process, as the processing liquid L₄, one capable of obtaining a hydrophilicizing effect different from that of the pure water L₀ is employed. This hydrophilicizing process prevents the pre-cleaning solution to be supplied in the subsequent pre-cleaning process from splashing off the surface of the substrate W and also suppresses the plating solution from being dropped off the surface of the substrate W.

Subsequently, the process controller 51 instructs the fluid supply device 200 to perform the pre-cleaning process (supply process f in FIG. 7) and the heated pure water supply to the rear surface (supply process a in FIG. 7). The fluid supply device 200 stops the supply of the pure water L₀ by closing the valve 260a and stops the supply of the processing solution L₄ by closing the valve 243, and supplies the pre-cleaning processing solution L₁ into the nozzle 144a by driving the pump 212 and the valve 213 (S303). Here, since the nozzle 144a is moved to the almost central position of the substrate W, the nozzle 144a becomes to supply the pre-cleaning solution L₁ toward the almost central portion of the substrate W. Since organic acid or the like is used as the pre-cleaning processing solution, it can eliminate copper oxide from copper wiring without causing galvanic corrosion, thereby increasing nucleation density in the plating process.

Thereafter, the fluid supply device 200 supplies the pure water to the fluid supply path 171. The heat exchanger 175 controls the temperature of the pure water sent into the fluid supply path 171 and supplies the temperature-controlled pure water to the bottom surface of the substrate W via the flow path 166 provided in the back plate 165, whereby the temperature of the substrate W is maintained at a temperature adequate for the plating process. Further, almost the same effect as described can be obtained even if starting the supply of the pure water into the fluid supply path 171 simultaneously with the above-described step S303.

Upon the completion of the pre-cleaning process, the process controller 51 instructs the fluid supply device 200 to perform the pure water process (supply process g in FIG. 7) (S305). The fluid supply device 200 stops the supply of the pre-cleaning processing solution L₁ by operating the pump 212 and the valve 213, and sends a certain amount of pure water L₀ into the nozzle 144a by opening the valve 260a. Then, by the supply of the pure water L₀ from the nozzle 144a, the pre-cleaning processing solution is substituted with the pure water. Through this pure water process, a generation of a process error due to the mixing of the acid pre-cleaning processing solution L₁ with the alkaline plating processing solution can be prevented.

After the pre-cleaning process A, the process controller 51 performs the plating process B. The plating process B includes a plating solution substitution process, a plating solution accumulation process, a plating solution process, and a pure water process.

The process controller 51 instructs the fluid supply device 200 and the nozzle driving device 205 to perform the plating solution substitution process (supply process e in FIG. 7). The fluid supply device 200 stops the supply of the pure water L₀ by closing the valve 260a, and supplies the plating solution L₃ into the nozzle 144c by operating the pump 232 and the valve 233. Meanwhile, the nozzle driving device 205 operates the first rotation driving mechanism 143 to thereby rotate the first arm 142 such that the nozzle 144c is moved (scanned) from the central portion of the substrate W to the periphery portion thereof and then back to the central portion again (S312). In the plating solution substitution process, the plating solution supply nozzle is moved from the central portion of the substrate W to the periphery portion thereof and then back to the central portion, and the substrate W is rotated at a relatively high rotational speed (“substitution X” process in FIG. 8). By this operation, the plating solution L₃ is diffused onto the substrate W, so that it becomes possible to rapidly substitute the pure water on the surface of the substrate W with the plating solution.

Upon the completion of the plating solution substitution process, the process controller 51 reduces the rotational speed of the substrate W held on the spin chuck 130, and instructs the fluid supply device 200 and the nozzle driving device 205 to perform the plating solution accumulation process. The fluid supply device 200 keeps on supplying the plating solution L₃, and the nozzle driving device 205 operates the first rotation driving mechanism 143, whereby the nozzle 144c is slowly moved from the central portion of the substrate W toward the periphery portion thereof (S314). The surface of the substrate W treated by the plating solution substitution process is covered with a sufficient amount of plating solution L₃. Further, when the nozzle 144c approaches close to the vicinity of the periphery portion of the substrate W, the process controller 51 further reduces the rotational speed of the substrate W (“solution accumulation Y” process in FIG. 8).

Subsequently, the process controller 51 instructs the fluid supply device 200 and the nozzle driving device 205 to perform the plating process. The nozzle driving device 205 operates the first rotation driving mechanism 143 to thereby rotate the first arm 142 so as to locate the nozzle 144c at an almost midway position between the central portion and the periphery portion of the substrate W.

Then, the fluid supply device 200 supplies the plating solution L₃ into the nozzle 144c discontinuously or intermittently by operating the pump 232 and the valve 233 (S317). That is, as illustrated in a “plating Z” process in FIGS. 7 and 8, the nozzle is located at a preset position and the plating solution is supplied discontinuously or intermittently. Since the substrate W is being rotated, the plating solution L₃ can be widely diffused onto the entire region of the substrate W even if it is supplied discontinuously (intermittently). Further, the processes of the steps S312, S314 and S317 may be performed repetitively. After a lapse of a predetermined time period after the supply of the plating solution L₃ is begun, the fluid supply device 200 stops the supply of the plating solution L₃, and the process controller 51 stops the supply of the heated pure water to the rear surface of the substrate W.

In the plating process B, in response to an instruction from the process controller 51, the fluid supply device 200 supplies the plating solution L₃ into the nozzle 144c by operating a supply mechanism. The supply mechanism conducts a transport control of the plating solution such that the pipe 141c inside a heat insulator and a temperature controller is filled up with the plating solution and the plating solution does not drop down from the nozzle 144c. A re-suction mechanism sucks the supplied plating solution, thus preventing the plating solution from dropping down from the nozzle 144c.

Further, the process controller 51 instructs the fluid supply device 200 and the nozzle driving device 205 to perform the pure water process (supply process g in FIG. 7). The process controller 51 increases the rotational speed of the substrate W held on the spin chuck 130, and the nozzle driving device 205 operates the first rotation driving mechanism 143 to thereby rotate the first arm 142 so as to locate the nozzle 144c at the central portion of the substrate W. Thereafter, the fluid supply device 200 supplies the pure water L₀ by opening the valve 260a (S321). In this way, the plating solution left on the surface of the substrate W is eliminated so that the plating solution can be prevented from being mixed with a post-processing solution.

After the plating process B, the process controller 51 conducts the post-cleaning process C. The post-cleaning process C includes a post chemical solution treatment and a pure water process.

The process controller 51 instructs the fluid supply device 200 to perform the post chemical solution treatment (supply process d in FIG. 7). The fluid supply device 200 stops the supply of the pure water L₀ by closing the valve 260a, and supplies the post-cleaning processing solution L₂ into the nozzle 144b by operating the pump 222 and the valve 223 (S330). The post-cleaning processing solution L₂ functions to remove residues on the surface of the substrate W or an abnormally precipitated plated film.

After the post chemical solution treatment, the process controller 51 instructs the fluid supply device 200 to perform the pure water process (supply process g in FIG. 7). The fluid supply device 200 stops the supply of the post-cleaning processing solution L₂ by operating the pump 222 and the valve 223, and supplies the pure water L₀ by opening the valve 260b (S331).

After the post-cleaning process C, the process controller 51 performs the rear surface/end surface cleaning process D. The rear surface/end surface cleaning process D includes a liquid removing process, a rear surface cleaning process and an end surface cleaning process.

The process controller 51 instructs the fluid supply device 200 to perform the liquid removing process. The fluid supply device 200 stops the supply of the pure water L₀ by closing the valve 260b, and the process controller 51 increases the rotational speed of the substrate W held on the spin chuck 130. This process aims at removing the liquid on the surface of the substrate W by drying the surface of the substrate W.

After the completion of the liquid removing process, the process controller 51 instructs the fluid supply device 200 to perform the rear surface cleaning process. First, the process controller 51 decreases the rotational speed of the substrate W held on the spin chuck 130. Thereafter, the fluid supply device 200 supplies pure water into the fluid supply path 171 (supply process a in FIG. 7). The heat exchanger 175 controls the temperature of the pure water sent to the fluid supply path 171 and supplies the temperature-controlled pure water to the rear surface of the substrate W via a flow path provided in the back plate 165 (S342). The pure water functions to hydrophilicize the rear surface side of the substrate W. Subsequently, the fluid supply device 200 stops the supply of the pure water into the fluid supply path 171, and instead supplies a rear surface cleaning solution into the fluid supply path 171 (S343). The rear surface cleaning solution functions to wash away and remove residues on the rear surface side of the substrate W in the plating process (supply process c in FIG. 7).

Thereafter, the process controller 51 instructs the fluid supply device 20 and the nozzle driving device 205 to perform the end surface cleaning process. The fluid supply device 200 stops the supply of the rear surface cleaning solution into the rear surface of the substrate W and instead supplies pure water, the temperature of which is controlled by the heat exchanger 175, into the fluid supply path 171 (S344) (supply process a in FIG. 7).

Subsequently, the nozzle driving device 205 rotates the second arm 152 so as to locate the nozzle 154 at an edge portion of the substrate W by means of driving the second rotation driving mechanism 153, and the process controller 51 increases the rotational speed of the substrate W up to about 150 to 300 rpm. Likewise, the nozzle driving device 205 rotates the first arm 142 so as to locate the nozzle 144b at the central portion of the substrate W by means of operating the first rotation driving mechanism 143. The fluid supply device 200 supplies the pure water L₀ into the nozzle 144b by opening the valve 260b, and supplies the outer periphery processing solution L₄ into the nozzle 154 by operating the pump 242 and the nozzle 243 (supply processes a and g in FIG. 7). That is, in this state, the pure water L₀ and the outer periphery processing solution L₄ are supplied to the central portion and the edge portion of the substrate W, respectively, while the temperature-controlled pure water is supplied to the rear surface of the substrate W (S346).

After the rear surface/end surface cleaning process D, the process controller 51 performs the drying process E. The drying process E includes a drying step.

The process controller 51 instructs the fluid supply device 200 and the nozzle driving device 205 to perform the drying step. The fluid supply device 200 stops the supply of all the processing solutions, and the nozzle driving device 205 retreats the first arm 142 and the second arm 152 from above the substrate W. Further, the process controller 51 increases the rotational speed of the substrate W up to about 800 to 1000 rpm to thereby dry the substrate W (S351). After the completion of the drying step, the process controller 51 stops the rotation of the substrate W. After the plating process is completed, the transfer arm 14A of the second substrate transfer mechanism 14 takes out the substrate W from the spin chuck 130 via the window 115.

Further, the process sequences of the pre-cleaning process, the plating process, the post-cleaning process, the rear surface/end surface cleaning process, and the drying process; the sequence of supplying or driving operations by the nozzle driving device 205, a temperature control fluid supply device 450 and the like; and the operation sequence of the various valves and pumps are all stored in the storage unit 53, and the process controller 51 sends instructions to each component to operate and control them based on the corresponding stored information.

Here, the operation of the temperature controller 145 in the whole plating process will be explained in connection with the case where the temperature controller 145 and the heat insulator 147 heat and keep the temperature of the plating processing solution every time they process the plating processing solution for one cycle of plating process. The temperature controller 145 heats the plating solution flowing in the pipe 141c up to the preset temperature. Specifically, as illustrated in FIG. 6, in an initial state (in a state of processing a first sheet of substrate), the temperature controller 145 heats the plating processing solution up to a preset temperature while the steps S301 to S312 are being performed, and the heat insulator 147 keeps the plating solution in the pipe 141c heated by the temperature controller 145 at a preset temperature (during a period marked by a dashed line (1) in FIG. 6). At this time, since the plating solution is prevented from dropping down from the nozzle 144c, it can be heated up to the preset temperature and maintained thereat. During the plating process B, since the plating processing solution is in a supplying state by each of the plating solution substitution process, the plating solution accumulation process and the plating solution process, the plating processing solution is kept being moved through the pipe, so that it is impossible (difficult) to heat most of it.

If the pure water process of step S321 is performed after the processing of the first sheet of substrate is completed, the supply of the plating processing solution is stopped, and the temperature controller 145 can resume the heating of the plating processing solution. A heating time of a plating processing solution for processing the second sheet of substrate becomes a time period between the end (step S321) of the plating process B of the first sheet of substrate and the start (step S312) of the plating process B of the second sheet of substrate (a period marked by a dashed dotted line (2) in FIG. 6). Likewise, a heating time of a plating processing solution for processing the third sheet of substrate becomes a time period represented by a dashed double-dotted line (3) in FIG. 6. That is, the periods (1) to (3) represent time periods for heating the plating processing solution for processing the substrate. As will be described later, a processing condition changes depending on the time period during which the processing solution is heated, in addition to the temperature of the plating processing solution during the plating process. Thus, it is desirable to set the periods (1) to (3) to be the same in order to implement uniform plating process. Moreover, the entire plating process may include a stabilization process using a dummy substrate (dummy wafer), whereby uniform film thickness can be obtained when processing the plurality of substrates W.

The transporting of the plating solution is conducted during a time period at a timing set by the process controller 51, and the entire amount of plating solution filled in the pipe 141c inside the temperature controller 145 and the heat insulator 147 is supplied during the one cycle of plating process. That is, if the one cycle of plating process is finished, the pipe 141c inside the temperature controller 145 and the heat insulator 147 is filled with a new plating solution not yet to be heated.

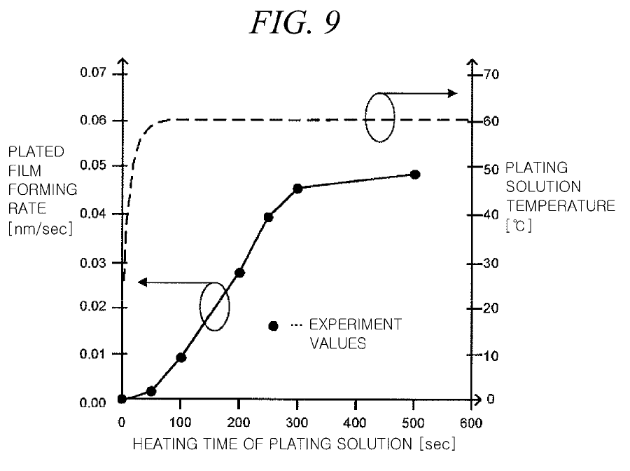

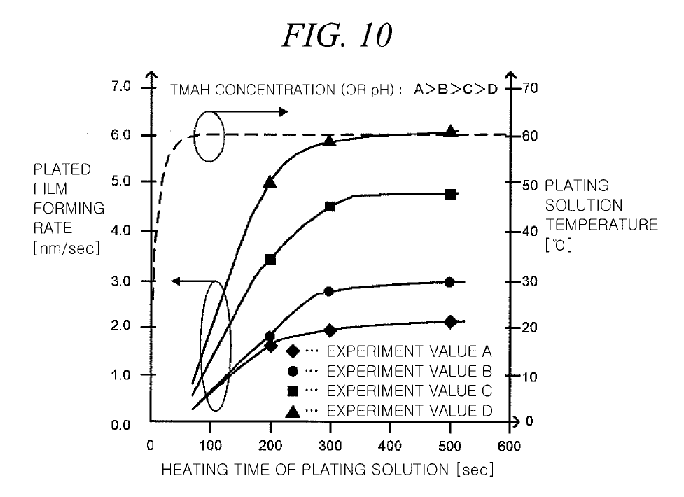

Here, a relationship between a plating solution temperature and a plated film forming rate will be described. FIG. 9 shows a relationship of a plating solution temperature and a plated film forming rate with respect to a heating time for a plating processing solution having a certain composition. FIG. 10 illustrates a relationship of a plating solution temperature and a plate film forming rate with respect to a heating time for each of a plurality of plating solutions having different TMAH compositions used as a PH adjuster. In these drawings, the amounts of the plating processing solutions corresponds to the capacities of the temperature controller 145 and the heat insulator 147.

In general, the plating processing solution is composed of a cobalt containing solution, a completing agent, a PH adjuster and a reducing agent. For the purpose of a stabilized plating process, it is necessary to heat and keep the temperature of the plating processing solution and to appropriately maintain a reaction temperature. Meanwhile, if the period for keeping the temperature of the plating processing solution becomes long, precipitation of the cobalt metal in the plating processing solution begins, and in case that the precipitated material is supplied onto the processing surface of the substrate, a plated film may contain foreign substances. Under a general temperature maintenance condition (60° C.), it can be seen that the precipitation occurs at about 30 minutes after the heating of the plating processing solution is begun.

Further, when using the plating processing solution having such composition, it seems that the reaction of the plating processing solution as the reducing agent can be facilitated or suppressed by controlling a pH concentration, which implies that a state of a plated film (which is the result of the reduction of the plating processing solution), particularly, a film forming rate can be controlled by adjusting the pH concentration.

As shown in a dashed line in FIG. 9, a time period (heating time) necessary to raise the temperature of the plating processing solution up to the target value, i.e., 60° C., is about 50 seconds. Then, the plated film forming rate marked by a solid line rapidly rises with the increase of the heating time, but only a slight increase is observed if the heating time exceeds 300 seconds. Further, as stated above, precipitation of metal ions in the plating processing solution occurs at about 1800 seconds (30 minutes). These results indicate that it is possible to implement stable plating process having a high film forming rate if using the plating processing solution heated and kept warm for a certain length of time rather than using the plating processing solution immediately after the temperature of the plating processing solution reaches the preset level (after heating it for about 50 seconds). In other words, in order to regulate the temperature of the plating processing solution to a temperature level suitable for the plating process, a heating time for maintaining the solution temperature at the optimum temperature as well as a heating time for increasing the solution temperature is also required.

FIG. 10 shows that a heating time (heating time required to stabilize the film forming rate) of the plating solution capable of obtaining a desired film forming rate depends on a composition ratio of the pH adjuster (TMAH). That is, it may be desirable to use a plating processing solution containing a high-concentration TMAH in case of a plating process requiring a high film forming rate, whereas it is desirable to use a plating processing solution containing a low-concentration TMAH in case that the heating time is required to be shortened.

When processing the plurality of substrates consecutively, there can be considered two cases that substrate processing time necessary for the processing of a single sheet of substrate is shorter than or longer than an appropriate heating time of the plating processing solution. In case that the substrate processing time is shorter than the heating time of the plating processing solution, the heating time of the plating processing solution can be shortened by reducing the concentration of the PH adjuster (TMAH). In this case, however, since the plating processing time necessary to obtain a required film thickness becomes longer, a start time of the following processing of a new substrate needs to be delayed. In this way, by controlling the heating time of the plating processing solution and the substrate processing time, a desired plating process can be implemented.

In the consecutive plating processes of the plurality of substrates, however, it may be difficult to control the heating time of the plating processing solution and the substrate processing time only by adjusting the pH adjuster of the plating solution because the substrate processing time necessary for the processing of the single sheet of substrate includes another processing time (processing time for each of the processes A, C, D and E in the example shown in FIG. 7) in addition to the processing time for the supply of the plating solution. In such case, the timing for the start of the heating of the plating processing solution or the start of the substrate processing (start of the supply of the plating solution) should be adjusted intentionally.

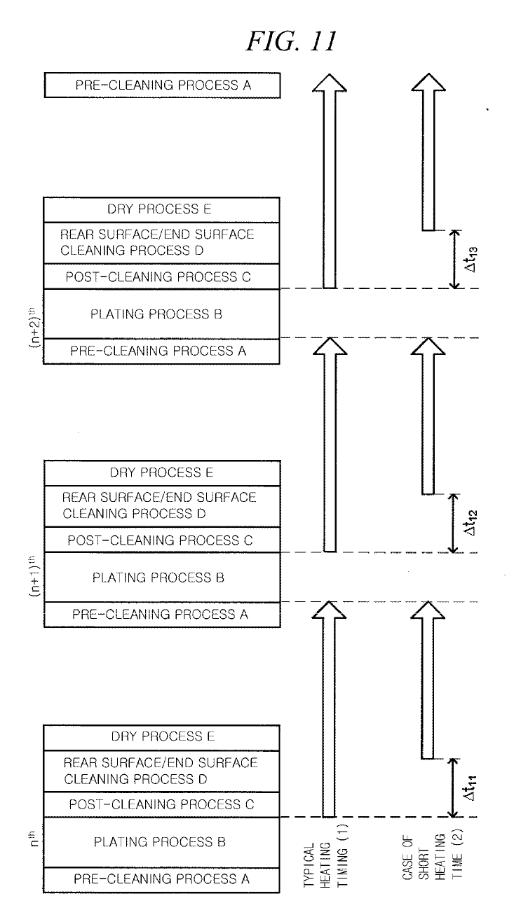

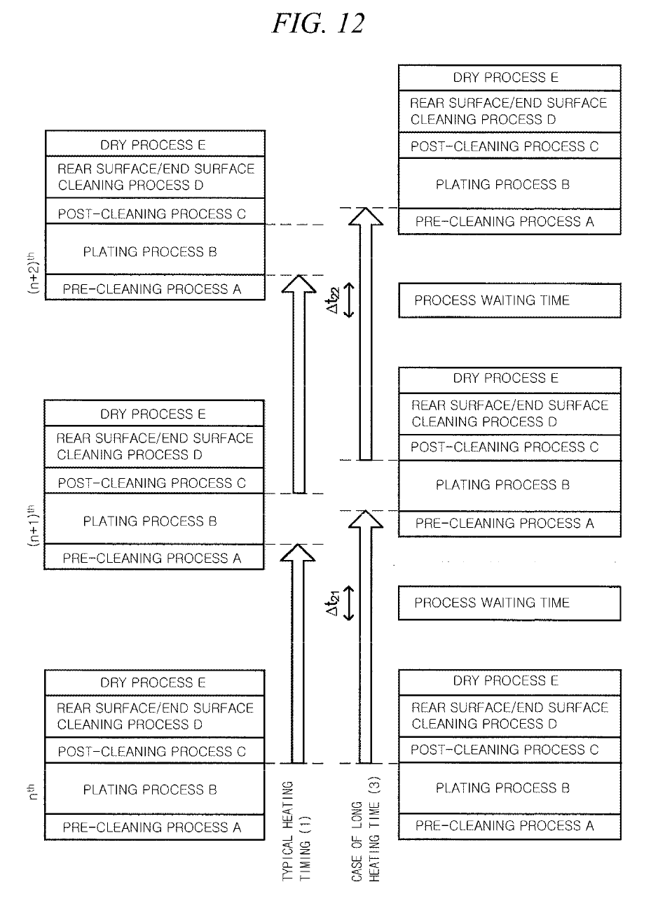

Now, a sequence setting method for intentionally adjusting the timing for the start of the heating time or the start of the substrate processing (start of the supply of the plating solution) in the consecutive plating processes of the plurality of substrates will be explained in conjunction with FIGS. 11 and 12. FIGS. 11 and 12 illustrate cases of performing the plating processes described in FIG. 6 on the plurality of substrates W.

As illustrated in FIG. 11, when plating a single sheet of substrate W, it is regarded that the pre-cleaning process A, the plating process B, the post-cleaning process C, the rear surface/end surface cleaning process D and the drying process E shown in FIGS. 6 and 7 are conducted. In this case, the processed substrate W is unloaded and a new substrate W is loaded during a time period before the pre-cleaning process A of the (n+1)^{th} process begins after the completion of the drying process E of the n^{th} process.

Here, in order to obtain the plating processing solution having a preset temperature and a preset film forming rate in the plating process B, the plating solution needs to be heated up to the preset temperature and maintained thereat for a certain length of time until the plating process B begins. Thus, in case of a typical heating timing (1) shown in FIG. 11, the heating of the plating processing solution begins after the post-cleaning process C starts, and the heating is maintained until the pre-cleaning process A is finished. During the plating process B, since the heated plating processing solution is discharged out from the nozzle 144c and a new plating processing solution is supplied into the temperature controller 145 and the heat insulator 147, the heating of plating processing solution is not actually performed.

There can be considered a case in which the heating time of the plating processing solution necessary to obtain the film forming rate required for the plating process is short, for example, a heating time shorter than a period from the start of the post-cleaning process C to the end of the pre-cleaning process A is required (timing (2) in FIG. 11). In such case, though the processing time of each process (A to E) can be adjusted, this method may not be desirable because it may cause changes of other parameters for the plating process. In this case, it may be desirable to start the heating and the temperature maintenance by the temperature controller 145 and the heat insulator 147 after times Δt₁₁, Δt₁₂, Δt₁₃, . . . elapse after each post-cleaning process C is started. This control can be carried out by an instruction sent from the process controller 51 to the temperature controller 145 and the heat insulator 147. As described, by starting the heating and temperature maintenance of the plating solution after the delay of as much as the times Δt₁₁, Δt₁₂, Δt₁₃, . . . every time each n^{th}, (n+1)^{th}, (n+2)^{th}, . . . substrate W is processed, the plating process with the preset film forming rate can be performed without changing the processing time of the pre-cleaning process A or the like. Furthermore, the delay times Δt₁₁, Δt₁₂, Δt₁₃, . . . for each substrate need not be the same all the time. When performing the plating processes on each substrate under different conditions, the delay times can be set differently according to each condition.

Meanwhile, There can be considered a case in which the heating time of the plating processing solution necessary to obtain the film forming rate required for the plating process is long, for example, a heating time longer than, a period from the start of the post-cleaning process C to the end of the pre-cleaning process A is required (timing (3) in FIG. 12). In this case, to the contrary to the timing (2) of FIG. 11, it may be desirable to provide waiting times Δt₂₁, Δt₂₂, . . . after each drying process E is finished and to delay the start of each pre-cleaning process A by as much as the times Δt₂₁, Δt₂₂, . . . , to thereby lengthen the heating time and the temperature maintenance time. This control can also be implemented by an instruction from the process controller 51. As described, by lengthening the heating time and the temperature maintenance time of the plating processing solution by means of providing the waiting times Δt₂₁, Δt₂₂, . . . every time each n^{th}, (n+1)^{th}, (n+2)^{th}, . . . substrate W is processed, the plating process with the preset film forming rate can be implemented without changing the processing time of the pre-cleaning process A or the like. Furthermore, the waiting times Δt₂₁, Δt₂₂, . . . for each substrate need not be the same all the time, like the above-stated delay times. When performing the plating processes on each substrate under different conditions, the waiting times can be set differently according to each condition.

In the electroless plating unit in accordance with the present embodiment illustrated in FIGS. 1 to 4, the plating solution is heated immediately before the plating process and is maintained at the set temperature for the preset time, and the once heated plating solution is all used up for a single cycle of plating process. Therefore, the temperature of the plating processing solution and the heating time can be controlled accurately, so that a process having a high balance between a deposition ability of the plating solution and a substrate processing rate can be implemented.

The above description of the present disclosure is provided for the purpose of illustration, and it would be understood by those skilled in the art that various changes and modifications may be made without changing technical conception and essential features of the present disclosure. Thus, it is clear that the above-described embodiments are illustrative in all aspects and do not limit the present disclosure. Further, various inventions can be conceived by combining a plurality of components described in the present embodiment appropriately. For example, some of the components described in the embodiment can be omitted, and components in different embodiments can be appropriately combined.

### INDUSTRIAL APPLICABILITY

The present disclosure can be applied to the fields of semiconductor manufacture.

What is claimed is:

1. A supply apparatus comprising:
a nozzle provided with a supply hole for discharging a plating solution toward a processing surface of a substrate held in a substantially horizontal direction;
a temperature controller for accommodating therein the plating solution in an amount necessary for processing a preset number of substrates, for controlling a temperature of the accommodated plating solution up to a preset temperature;
a heat insulator disposed between the nozzle and the temperature controller, for maintaining the plating solution, whose temperature has been controlled by the temperature controller, at the preset temperature; and
a transporting mechanism for transporting the plating solution, whose temperature has been controlled up to the preset temperature by the temperature controller, toward the supply hole of the nozzle via the heat insulator.

2. The supply apparatus of claim 1, wherein the temperature controller accommodates the plating solution in an amount necessary for processing a single sheet of substrate and then controls the accommodated plating solution up to the preset temperature, and
the transporting mechanism transports the whole amount of the processing solution whose temperature has been controlled by the temperature controller toward the supply hole of the nozzle via the heat insulator at one time.

3. The supply apparatus of claim 1, further comprising:
a re-suction mechanism for sucking the plating solution still left in the nozzle after the transporting mechanism transports the whole amount of the plating solution.

4. A semiconductor manufacturing apparatus comprising:
a processing chamber for accommodating a substrate therein;
a holding unit disposed inside the processing chamber, for holding the substrate;
a supply apparatus as claimed in claim 1, disposed in the processing chamber; and
a loading/unloading mechanism for loading and unloading the substrate into and from the processing chamber.

5. A semiconductor manufacturing apparatus for performing a plating process on a plurality of substrates consecutively, the apparatus comprising:
a temperature controller for accommodating therein a preset amount of plating solution necessary for processing a single sheet of substrate and for controlling the accommodated plating solution up to a preset temperature;
a holding unit for holding the substrates one by one at a preset position;
a nozzle provided with a supply hole for discharging the plating solution, whose temperature has been controlled by the accommodation in the temperature controller, toward a processing surface of the substrate held by the holding unit;
a transporting mechanism for transporting the whole amount of plating solution, whose temperature has been controlled up to the preset temperature by the accommodation in the temperature controller, toward the supply hole of the nozzle whenever processing a single sheet of substrate held by the holding unit; and
a control unit for controlling timing for transporting the plating solution by the transporting mechanism.

6. The semiconductor manufacturing apparatus of claim 5, wherein the control unit further controls timing for controlling a temperature of the plating solution up to the preset temperature by the temperature controller.

7. The semiconductor manufacturing apparatus of claim 5, wherein the control unit controls the supply of the preset amount of plating solution and timing for the supply by the transporting mechanism, and controls the supply of the plating solution onto a processing surface of the substrate and also controls a temperature control time of the preset amount of plating solution by the temperature controller.

8. A semiconductor manufacturing method comprising:
accommodating a preset amount of plating solution necessary for processing a single sheet of substrate in a temperature control vessel;
heating the plating solution accommodated in the temperature control vessel; and
after the plating solution reaches a preset temperature, transporting the whole amount of plating solution accommodated in the temperature control vessel at one time toward a supply hole, provided in a nozzle connected to the temperature control vessel, to discharge the plating solution onto a processing surface of the substrate at one time.

9. The semiconductor manufacturing method of claim 8, wherein the plating solution still left in the nozzle after the whole amount of plating solution accommodated in the temperature control vessel is transported toward the supply hole is sucked.

10. The semiconductor manufacturing method of claim 8, wherein the transporting of the plating solution accommodated in the temperature control vessel toward the supply hole is performed after a heating of the plating solution is continued for a predetermined time after the plating solution reaches the preset temperature.

11. The semiconductor manufacturing method of claim 8, wherein timing for starting heating is determined depending on the kind of the plating solution prior to heating the plating solution, and the heating of the plating solution begins based on the determined timing.

12. The semiconductor manufacturing method of claim 10, wherein a period during which the heating of the plating solution is to be continued is determined depending on the kind of the plating solution prior to heating the plating solution, and the heating of the plating solution is continued during the determined period after reaching the preset temperature.
